(19) United States
(12) Patent Application Publication
(10) Pub. No.: US 2026/0015730 A1
(43) Pub. Date: Jan. 15, 2026

(54) SUBSTRATE PROCESSING APPARATUS, METHOD OF PROCESSING SUBSTRATE, METHOD OF MANUFACTURING SEMICONDUCTOR DEVICE, GAS SUPPLY SYSTEM, AND RECORDING MEDIUM

(71) Applicant: Kokusai Electric Corporation, Tokyo (JP)

(72) Inventors: Koichi Honda, Toyama-shi (JP); Katsuji Oshida, Toyama-shi (JP); Kenji Shirako, Toyama-shi (JP)

(73) Assignee: Kokusai Electric Corporation, Tokyo (JP)

(21) Appl. No.: 19/332,713

(22) Filed: Sep. 18, 2025

Related U.S. Application Data
(63) Continuation of application No. PCT/JP2023/034381, filed on Sep. 21, 2023.

(51) Int. Cl. C23C 16/52; C23C 16/448; C23C 16/455; H01L 21/02

(52) U.S. Cl. CPC C23C 16/52; C23C 16/4485; C23C 16/45561; H01L 21/0217; H01L 21/02271

(57) ABSTRACT

A technique includes: (a) a pair of injectors each supplying a film formation gas toward a substrate; (b) a pair of tanks connected to the pair of injectors respectively and accumulating the gas; (c) a pair of opening and closing valves controlling fluid communication of the gas between the pair of injectors and the pair of tanks in a corresponding manner, respectively; (d) a pair of pressure gauges measuring internal pressures of the pair of tanks, respectively, during accumulation of the gas; (e) a pair of flow rate limiters supplying the gas to the pair of tanks at a set flow rate set in advance to form a standard accumulation amount as a target amount of the gas, respectively; and (f) a controller capable of performing correcting the set flow rate so as to approach the standard accumulation amount.

### CROSS-REFERENCE TO RELATED APPLICATION

This application is a Bypass Continuation application of PCT International Application No. PCT/JP2023/034381, filed on Sep. 21, 2023, the disclosure of which is incorporated herein in its entirety by reference.

### TECHNICAL FIELD

The present disclosure relates to a substrate processing apparatus, a method of processing a substrate, a method of manufacturing a semiconductor device, a gas supply system, and a recording medium.

### BACKGROUND

In the related art, a semiconductor manufacturing apparatus that manufactures semiconductor devices is known as an example of a substrate processing apparatus. As an example of the semiconductor manufacturing apparatus, a vertical semiconductor manufacturing apparatus that processes a plurality of substrates while holding them in multiple stages in a vertical direction is disclosed in the related art. In the vertical semiconductor manufacturing apparatus, a film formation process that forms a predetermined film on a surface of a substrate may be performed as substrate processing.

In addition, a semiconductor device in which a gap between a substrate and a semiconductor element mounted on the substrate is sealed with a liquid epoxy resin composition is disclosed in the related art. In addition, techniques in which a precursor gas and an inert gas are supplied to a substrate using two gas supply systems are disclosed in the related art.

During a film formation process, when a process gas such as a precursor gas is injected to a substrate in a process chamber, exposure of the precursor gas to the surface of the substrate is not uniform, which may result in a decrease in an in-plane uniformity of a film on the substrate or a decrease in step coverage. Hereinafter, the process gas is also referred to simply as a “gas.” In addition, the step coverage is also referred to as “S/C.”

Herein, when a gas supply system is used in which the same type of gas is accumulated in tanks of the same capacity respectively connected to two or more injectors and the accumulated gas is supplied to the substrate, it may be desirable to uniformly form supply amounts of the respective gases from two or more gas supply systems, from the viewpoint of improving the uniformity of the film on the substrate and S/C.

### SUMMARY

Some embodiments of the present disclosure provide a technique capable of improving uniformity of supply amounts of gases supplied to a substrate from two or more gas supply systems.

According to some embodiments of the present disclosure, there is provided a technique that includes: (a) a pair of injectors each configured to supply a film formation gas toward a substrate; (b) a pair of tanks connected to the pair of injectors respectively and configured to accumulate the gas; (c) a pair of opening and closing valves configured to control fluid communication of the gas between the pair of injectors and the pair of tanks in a corresponding manner, respectively; (d) a pair of pressure gauges configured to measure internal pressures of the pair of tanks, respectively, during the accumulation of the gas; (e) a pair of flow rate limiters configured to supply the gas to the pair of tanks at a set flow rate set in advance to form a standard accumulation amount as a target amount of the gas, respectively; and (f) a controller configured to be capable of performing: accumulating the gas in one of the pair of tanks while controlling the fluid communication by a corresponding opening and closing valve of the pair of opening and closing valves; measuring the internal pressure of the one of the pair of tanks by a corresponding pressure gauge of the pair of pressure gauges during the accumulation of the gas; calculating an integrated flow rate of the gas to the one of the pair of tanks or an accumulation amount in the one of the pair of tanks; and correcting the set flow rate so as to approach the standard accumulation amount based on the measured internal pressure and the calculated integrated flow rate or the calculated accumulation amount.

### BRIEF DESCRIPTION OF DRAWINGS

The accompanying drawings, which are incorporated in and constitute a part of the specification, illustrate embodiments of the present disclosure.

FIG. 1 is a front view illustrating a substrate processing apparatus according to some embodiments of the present disclosure, partially cut along a vertical plane in a depth direction.

FIG. 2 is a cross-sectional view taken along line 2-2 in FIG. 1, illustrating the substrate processing apparatus according to the embodiments of the present disclosure, cut in a horizontal direction.

FIG. 3 is a front view illustrating a U-turn nozzle used in a substrate processing apparatus according to some embodiments of the present disclosure.

FIG. 4 is a block diagram illustrating a gas supply system of a substrate processing apparatus according to some embodiments of the present disclosure.

FIG. 5 is a block diagram illustrating a control system of a controller of a substrate processing apparatus according to some embodiments of the present disclosure.

FIG. 6 is a flowchart illustrating a correction process in substrate processing according to some embodiments of the present disclosure.

FIG. 7 is a graph illustrating fluctuation in an internal pressure of each of two tanks accumulating a gas when a flow rate of the gas is not corrected.

FIG. 8 is a flowchart illustrating a substrate processing process according to some embodiments of the present disclosure.

FIG. 9 is a flowchart illustrating a correction process in substrate processing according to a modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

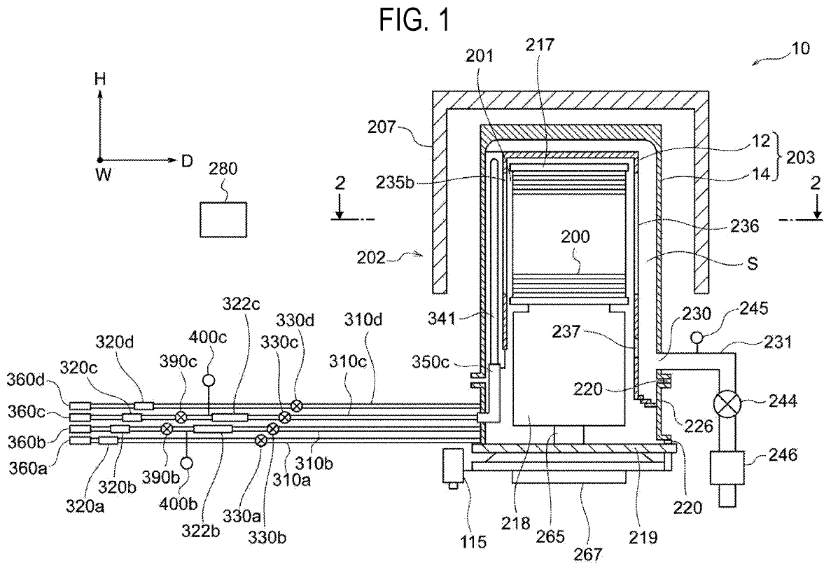

Some embodiments of the present disclosure will now be described with reference to FIGS. 1 to 9. In the drawings, substantially identical elements are denoted by the same reference numerals, and descriptions thereof in the present disclosure will not be duplicated. The drawings used in the following description are schematic, and dimensional relationships, ratios, and the like of various elements shown in the drawings may not match actual ones. Further, dimensional relationships, ratios, and the like of various elements between plural figures may not match each other. Furthermore, unless otherwise specified in the present disclosure, each element is not limited to one, and may be present in plural.

Note that in the present disclosure, an expression of a numerical range such as “3 slm to 4 slm” means that a lower limit and an upper limit are included in that range. Therefore, for example, “3 slm to 4 slm” means “3 slm or more and 4 slm or less.” The same applies to other numerical ranges.

### <Overall Configuration of Substrate Processing Apparatus>

First, an overall configuration of a substrate processing apparatus 10 according to some embodiments of the present disclosure will be described with reference to FIGS. 1 to 5. An up-down direction H of the apparatus indicates a vertical direction, a width direction W of the apparatus indicates a horizontal direction, and a depth direction D of the apparatus indicates the horizontal direction.

As shown in FIG. 1, the substrate processing apparatus 10 includes a control part 280 configured to control each component and a process furnace 202. The process furnace 202 includes a furnace heater 207, which is a heating apparatus. The furnace heater 207 is formed in a cylindrical shape and is supported by a heater base (not shown) so as to be installed in the up-down direction H of the apparatus. The furnace heater 207 also functions as an activator configured to activate a process gas with heat. Details of the control part 280 will be described later.

A reaction tube 203, which serves as a process tube constituting a reaction container, is disposed upright inside the furnace heater 207. The reaction tube 203 corresponds to a process container of the present disclosure. The reaction tube 203 is made of a heat-resistant material such as quartz (SiO₂) or silicon carbide (SIC). The substrate processing apparatus 10 is of a so-called hot-wall type.

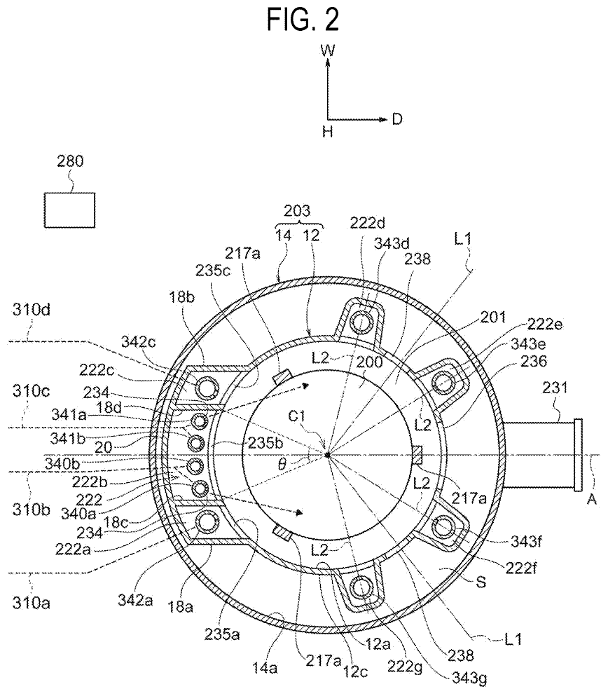

As shown in FIG. 2, the reaction tube 203 includes a cylindrical inner tube 12 and a cylindrical outer tube 14 installed to surround the inner tube 12. The outer tube 14 surrounds the inner tube 12 to form a gap as an exhaust space S between the outer tube 14 and a cylindrical portion of the inner tube 12. The inner tube 12 is disposed to be concentric with the outer tube 14. The inner tube 12 is an example of a tube member.

The inner tube 12 includes an opened lower end and an upper end closed by a flat wall. Further, the outer tube 14 includes an opened lower end and an upper end closed by a flat wall.

As shown in FIG. 1, inside the inner tube 12, a process chamber 201 in which wafers 200 as substrates are processed is formed. Further, a boat 217 may be accommodated in the process chamber 201. The boat 217 is an example of a substrate holder configured to be capable of holding the wafers 200 in a horizontal posture and arranged in multiple stages along the vertical direction. The inner tube 12 surrounds the wafers 200 accommodated in the process chamber 201. The wafers 200 are arranged inside the cylindrical portion of the inner tube 12 along an axial direction of the cylindrical portion.

Further, as shown in FIG. 2, the inner tube 12 includes a supply buffer 222 formed to protrude outward and serving as a nozzle chamber. The supply buffer 222 is a supply space in which nozzles configured to supply a process gas are arranged. Details of the inner tube 12 will be described later.

The lower end of the reaction tube 203 is supported by a cylindrical manifold 226. A flange is formed at an upper end of the manifold 226, and the lower end of the outer tube 14 is placed on this flange. A seal 220 such as an O-ring is placed between this flange and the lower end of the outer tube 14, such that the inside of the reaction tube 203 is formed in an airtight state.

A disc-shaped seal cap 219 is air-tightly attached to a lower end opening of the manifold 226 via the seal 220 such as an O-ring. Therefore, the lower end opening of the reaction tube 203, i.e., the opening of the manifold 226, is air-tightly closed.

A boat support 218 configured to support the boat 217 is installed on the seal cap 219. The boat support 218 is made of a heat-resistant material such as SiO₂ or SiC, and functions as a heat insulator.

The boat 217 is installed upright on the boat support 218. The boat 217 is made of a heat-resistant material such as SiO₂ or SiC. As shown in FIG. 2, the boat 217 includes a bottom plate fixed to the boat support 218 and a top plate disposed above the bottom plate. A plurality of posts 217a are installed between the bottom plate and the top plate in a bridged sated.

The boat 217 holds a plurality of wafers 200 to be processed in the process chamber 201 in the inner tube 12. As shown in FIG. 2, the plurality of wafers 200 are supported by the posts 217a of the boat 217 in such a state that the wafers 200 are arranged in a horizontal posture at certain intervals and with centers of the wafers 200 aligned with each other. A loading direction of the plurality of wafers 200 is the axial direction of the reaction tube 203.

A rotator 267 configured to rotate the boat is installed below the seal cap 219. A rotary shaft 265 of the rotator 267 is connected to the boat support 218 through the seal cap 219. The rotator 267 rotates the boat 217 via the boat support 218, thereby rotating the wafers 200.

The seal cap 219 is vertically raised or lowered by an elevator 115 as elevating mechanism installed outside the reaction tube 203. This allows the boat 217 to be loaded into or unloaded from the process chamber 201.

The manifold 226 is provided with a plurality of nozzle supports configured to penetrate the manifold 226 so as to support a gas nozzle 342a, a return nozzle 340, a return nozzle 341, and a gas nozzle 342c, each of which is configured to supply a gas to the inside of the process chamber 201. In the embodiments, four nozzle supports are installed at the supply buffer 222. In FIG. 1, the return nozzle 341 and a nozzle support 350c configured to support the return nozzle 341 are shown as representative examples. The four nozzle supports are made of, for example, metal.

As shown in FIG. 1, gas supply pipes 310a to 310d configured to supply a gas to the inside of the process chamber 201 are connected to one ends of the four nozzle supports, respectively. In addition, the gas nozzle 342a, the return nozzle 340, the return nozzle 341, and the gas nozzle 342c are connected to the other ends of the nozzle supports, respectively. The gas nozzles 342a and 342c are made of, for example, a heat-resistant material such as SiO₂. Details of the gas nozzles 342a and 342c will be described later.

### (Gas Supply Pipe)

The supply pipe 310a is in fluid communication with the nozzle 342a via a nozzle support (not shown). Similarly, the supply pipe 310d communicates with the corresponding gas nozzle 342c. The supply pipe 310b is in fluid communication with the return nozzle 340.

The return nozzle 340 includes a gas nozzle 340a and a gas nozzle 340b. The supply pipe 310c is in fluid communication with the return nozzle 341 via the nozzle support 350c. The return nozzle 341 includes a gas nozzle 341a in the second row from the top in FIG. 2 and a gas nozzle 341b in the third row from the top in FIG. 2.

At the supply pipe 310a, a supply source 360a configured to supply an assist gas as a process gas, a mass flow controller (MFC) 320a as an example of a flow rate controller, and a valve 330a as an opening and closing valve are installed, sequentially from the upstream side in a gas flow direction.

Further, at the supply pipe 310b, a vaporizer 360b as a gas supply source configured to supply a precursor gas as a process gas, a MFC 320b, a valve 390b, a tank 322b, and a valve 330b are installed, sequentially from the upstream direction to the downstream direction. The MFC 320b and a MFC 320c are a pair of flow rate limiters of the present disclosure configured to supply gases to a pair of tanks respectively at a set flow rate set to form a standard accumulation amount as a target amount of gas.

In the embodiments, in a state where the flow rate of gas cannot be limited to the set flow rate, internal control valves (not shown) of the MFCs 320b and 320c are fully open or fully closed. This is also referred to as a saturated state or an uncontrollable state. In the present disclosure, the internal control valves may not be fully opened or fully closed in the state in which the flow rate of the gas cannot be limited to the set flow rate. The control valves may be in a state between a fully-opened state and a fully-closed state.

Although not shown, each of the MFCs 320b and 320c includes an orifice and a control valve configured to control a pressure of a gas on a primary side of the orifice. Both the MFCs 320b and 320c use a choke flow of the orifice to control a flow rate of the gas.

The gas supply pipe 310c is provided with a vaporizer 370c at the most upstream position in the gas flow direction. In addition, the gas supply pipe 310b is provided with a vaporizer 360c as a gas supply source configured to supply a precursor gas as a process gas, a MFC 320c, a valve 390c, a tank 322c, and a valve 330c, sequentially from the upstream direction to the downstream direction on the downstream side of the vaporizer. The valves 390b and 390c are a pair of opening and closing valves of the present disclosure configured to control fluid communication of the gases between the return nozzles 340 and 341 and the tanks 322b and 322c in a corresponding manner, respectively.

At the gas supply pipe 310d, a vaporizer 360d as a gas supply source configured to supply a reaction gas as a process gas, a MFC 320d, and a valve 330d are respectively installed, sequentially from the upstream direction.

### (Vaporizer)

The vaporizers 360a to 360d vaporize a gas in a liquid state at a target temperature and provide the vaporized gas to corresponding MFCs 320a to 320d, respectively, at a pressure determined according to a saturated vapor pressure at the target temperature. The vaporizers 360b and 360c are a pair of vaporizers of the present disclosure. The vaporizers 360b and 360c provide the vaporized gas to the MFCs 320b and 320c, respectively.

The reaction gas is supplied from the gas supply pipe 310d. The precursor gas is supplied from the gas supply pipes 310b and 310c. Although not shown, at each gas nozzle in the embodiments, a gas supply pipe configured to supply a nitrogen (N₂) gas or the like as a purge gas or an assist gas are also installed, together with a MFC and a valve.

A plurality of exhaust slits, including a main exhaust slit 236 and a sub-exhaust slit 238, are formed in a sidewall of the inner tube 12. The plurality of exhaust slits exhaust a gas in the inner tube 12 to the exhaust space S. The main exhaust slit 236 in the embodiments corresponds to an exhauster and a main exhauster in the present disclosure. The sub-exhaust slit 238 in the embodiments corresponds to an exhauster and a sub-exhauster in the present disclosure. In the embodiments, the number of a plurality of exhaust slits is three, which includes one main exhaust slit 236 and two sub-exhaust slits 238. In the embodiments of the present disclosure, the number of the plurality of exhaust slits may be at least two or more.

A lower exhaust port 237 is an auxiliary opening that is provided at the inner tube below the main exhaust slit 236. The lower exhaust port 237 exhausts a gas in the vicinity of the boat support 218. Note that in the present disclosure, the lower exhaust port 237 may not be provided.

The outer tube 14 of the reaction tube 203 is provided with an exhaust port 230. The exhaust port 230 is formed below the lower end of the main exhaust slit 236. The exhaust port 230 is configured to provide fluid communication between the exhaust space S and the outside of the reaction tube 203. As shown in FIG. 2, the exhaust port 230 is disposed on the opposite side of the supply buffer 222. In a plane view, the supply buffer 222, the exhaust port 230, and the main exhaust slit 236 to be described later are arranged to be aligned on a straight line passing through the center of the substrate.

The exhauster may be, for example, an exhaust port including an opening that allows the inside of the process chamber 201 to be in fluid communication with the exhaust space S and indirectly exhausting a gas in the process chamber 201 to the outside via the exhaust space S. Alternatively, the exhauster may be an opening that is directly connected to an exhaust duct to be described later. The exhaust duct 231 guides the exhaust from the reaction tube 203 to a vacuum pump 246 as a vacuum exhauster.

At the exhaust duct 231, a pressure sensor 245 configured to detect an internal pressure of the process chamber 201 and an auto pressure controller (APC) valve 244 as a pressure regulator are installed. A downstream side of the vacuum pump 246 is connected to a waste gas treatment apparatus and the like (not shown). By controlling an output of the vacuum pump 246 and a degree of opening the APC valve 244, the process chamber 201 can be vacuum-exhausted such that the internal pressure of the process chamber 201 reaches a predetermined pressure (i.e., degree of vacuum).

In addition, a temperature sensor (not shown) as a temperature detector is installed inside or on an outer wall of the reaction tube 203. By regulating power supplied to the furnace heater 207 based on the temperature information detected by the temperature sensor, a temperature distribution in the process chamber 201 becomes a desired temperature distribution.

Next, the supply buffer 222, the return nozzles 340 and 341 as a first injector, and the exhaust slits including the main exhaust slit 236 and the sub-exhaust slit 238 in the substrate processing apparatus 10 according to the embodiments of the present disclosure will be specifically described. Note that the first injector is not limited to a tubular member such as a nozzle, as long as it is possible to inject the precursor gas into the process chamber 201.

### (Supply Buffer)

As shown in FIG. 2, the supply buffer 222 is a region inside the inner tube 12 which is formed by protruding a cylindrical portion outward to minimize a volume of the inner tube 12 to accommodate a nozzle. The supply buffer 222 may be disposed in the exhaust space S outside the inner tube 12.

The supply buffer 222 includes a first partition 18a, a second partition 18b, and an arc-shaped side plate 20 connecting an outer end of the first partition 18a and an outer end of the second partition 18b. Both the first partition 18a and the second partition 18b extend from an outer peripheral surface 12c of the inner tube 12 toward the outer tube 14.

A third partition 18c and a fourth partition 18d, which are plate-shaped and extend vertically, are installed inside the supply buffer 222. The third partition 18c and the fourth partition 18d extend from the side plate 20 toward the inside of the inner tube 12 to a position at which a distance from the center C1 of the wafer 200 is approximately equal to a radius of the inner tube 12.

The supply buffer 222 is divided into three portions 222a, 222b, and 222c along a circumferential direction of the cylindrical portion by the third partition 18c and the fourth partition 18d.

As shown in FIG. 2, the portions 222a, 222b, and 222c of the supply buffer 222 are in fluid communication with the inner tube 12 independently by supply ports 235a, 235b, and 235c, respectively. The supply ports 235a and 235c may be formed as horizontally elongated slits in one-to-one correspondence with the wafers 200, and the supply port 235b can be formed as a single vertically elongated slit that opens across the entirety of the wafers 200 as shown in FIG. 1.

### (First Injector)

The return nozzles 340 and 341, which are a plurality of gas nozzles, are installed in the portion 222b of the supply buffer 222, extend along the axial direction of the cylindrical portion, and are configured to be capable of supplying the same precursor gas. In the present disclosure, the plurality of nozzles may not be return nozzles, and may be, for example, an array of plural straight nozzles (nozzle array) independent of each other.

### (Return Nozzle)

In each return nozzle 340 of the embodiments, the four gas nozzles 340a, 340b, 341a, and 341b are formed by two return nozzles 340 and 341. That is, the gas nozzles 340a and 340b adjacent to each other on the lower side in the width direction W in FIG. 2 are formed by one return nozzle 340. In addition, the gas nozzles 341a and 341b adjacent to each other on the upper side opposite the gas nozzles 340a and 340b in the width direction W are formed by another return nozzle 341.

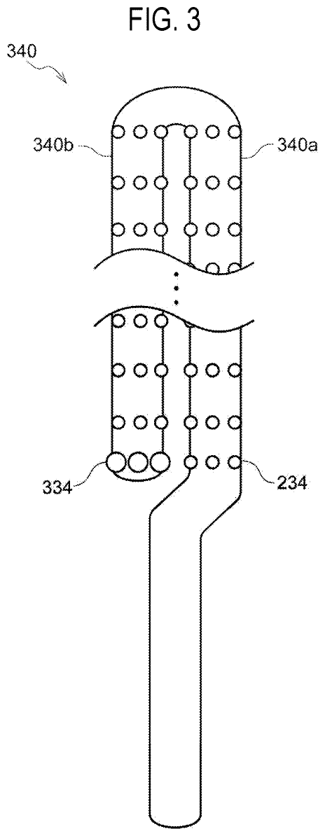

As shown in FIG. 3, the return nozzle 340 includes a forward pipe 340a and a return pipe 340b. An upper end of the forward pipe 340a and an upper end of the return pipe 340b are in fluid communication with each other, such that the precursor gas flows therethrough. The return nozzle 341 is configured to be in plane symmetry with the return nozzle 340 with respect to a virtual plane A passing through the central axis of the reaction tube 203. The return pipes of the return nozzles 340 and 341 are adjacent to each other and the forward pipes of the return nozzles 340 and 341 are arranged apart from each other. In addition, the return pipe 340b, the forward pipe 340a, the forward pipe 341a, and the return pipe 341b are arranged side by side along the supply port 235b so that the distances from the wafer 200 are approximately equal.

The return nozzles 340 and 341 are a pair of injectors of the present disclosure configured to supply a film formation gas toward the wafer 200, respectively. In addition, the return nozzles 340 and 341 are U-turn nozzles of the present disclosure. The return nozzles 340 and 341 include four or more injection holes arranged in a plane parallel to the wafer 200. Specifically, as shown in FIG. 3, three injection holes 234 are formed in each of the forward pipe 340a and the return pipe 340b, that is, a total of six injection holes 234 are formed for each wafer 200. The injection holes 234 are formed. The injection holes 234 vertically penetrate the forward pipe 340a and the return pipe 340b to provide a flow path that is in fluid communication between the inside and outside of them. The gas is radially injected from the forward pipe 340a and the return pipe 340b.

In addition, at the lowest position of the return pipe 340b, three expanded injection holes 334, which are larger in diameter than the injection holes 234, are formed instead of the three injection holes 234.

In this way, the return nozzles 340 and 341 provide injection holes distributed over the width of the portion 222b of the supply buffer 222. As a result, a gas leaving the supply port 235b spreads to the inner diameter of the inner tube 12 and flows on the surface, and is discharged from the main exhaust slit 236 and the sub-exhaust slit 238. At this time, in a case where there is a bias or time difference in the supply from the return nozzles 340 and 341, the plane symmetry based on the virtual plane A is broken, and a flow that returns to the supply port 235b without being discharged from the exhaust slit may occur. This is undesirable because it slows down exhaust and makes the gas exposure uneven across the surface of the wafer 200.

### <Exhaust Slit>

As shown in FIG. 2, the plurality of exhaust slits including the main exhaust slit 236 and the sub-exhaust slit 238 are formed in the sidewall of the cylindrical portion to exhaust the precursor gas from the inside of the cylindrical portion. In the present disclosure, the main exhaust slit 236 may not be provided.

### (Main Exhaust Slit)

The main exhaust slit 236 is formed in the sidewall of the cylindrical portion on the opposite side of the supply buffer 222 with respect to the center C1 of the wafer 200. The main exhaust slit 236 opens on the side of each wafer 200 and exhausts the precursor gas and the like that flows over the wafer 200. The main exhaust slit 236 can be formed as a single opening extending between the side of the top wafer 200 and the side of the bottom wafer 200, or as a plurality of holes distributed between them.

### (Sub-Exhaust Slit)

The two sub-exhaust slits 238 open with the virtual plane A, which is set on the inside of the cylinder portion, sandwiched from both sides. As shown in FIG. 2, the virtual plane A is set to pass through a circumferential center of the cylinder portion at the boundary between the supply buffer 222 and the cylinder portion and an axis of the cylinder portion in plane view. The axis of the cylinder portion overlaps with the center of the wafer 200.

As a pair of exhaust slits, the two sub-exhaust slits 238 sandwich the main exhaust slit 236 in the same height range as the main exhaust slit 236. In plane view, a first virtual line L1 connecting the center of the sub-exhaust slit 238 and the center C1 of the wafer 200 is set. In the embodiments, an angle between the first virtual line L1 and the virtual plane A, measured with the center of the supply buffer 222 set at 0 degrees, is an obtuse angle.

As shown in FIG. 2, the width of each of the two sub-exhaust slits 238 in the circumferential direction of the cylinder portion is smaller than the width of the main exhaust slit 236 at the same height.

As shown in FIG. 2, the return nozzles 340 and 341 and the two sub-exhaust slits 238 are configured in symmetry with respect to the virtual plane A.

### (Tank)

As shown in FIG. 1, the substrate processing apparatus 10 according to the embodiments of the present disclosure further includes the tanks 322b and 322c connected to the return nozzles 340 and 341. The tanks 322b and 322c are the same in volume and can accumulate the precursor gas alone so that the precursor gas is not mixed with a carrier gas. The tanks 322b and 322c supply the accumulated precursor gas to the return nozzles 340 and 341 almost simultaneously in a pulsed manner via an opening and closing valve. The tanks 322b and 322c are a pair of tanks of the present disclosure. Depending on a vapor pressure of the precursor gas, internal pressures of the tanks 322b and 322c are usually equal to or lower than the atmospheric pressure. The tanks 322b and 322c may be isothermal tanks charged with metal wool or filaments.

In other words, in the embodiments, flush supply of a high-concentration precursor gas may be performed. In the flush supply, the precursor gas accumulated in the tanks 322b and 322c is supplied at a high flow rate from the tanks 322b and 322c toward the reaction tube 203. The precursor gas supplied at the high flow rate is also referred to as a “flush flow.” The precursor gas of the flush flow flows at a relatively high speed on the surface of the wafer 200 inside the cylinder portion of the inner tube 12 during the film formation process.

The flush supply exposes the entire surface of the wafer 200 to a high-speed flow of precursor gas during the film formation process. A high-speed gas flow is one of the most effective methods of promoting gas replacement inside fine structures such as trenches and holes formed on the surface of the wafer 200, and is particularly useful in processing patterned wafers with high aspect ratios.

Note that the present disclosure is not limited to the flush supply of the precursor gas, and may be applied to, for example, high flow supply of ammonia (NH₃) as a purge gas by using a typical MFC.

### (Second Injector)

As shown in FIG. 2, the substrate processing apparatus 10 according to the embodiments of the present disclosure further includes gas nozzles 342a and 342c as a second injector configured to supply an assist gas. The gas nozzles 342a and 342c are installed at the portions 222a and 222c on both sides of the supply buffer 222, respectively. In the present disclosure, the second injector may not be provided. Note that the second injector is not limited to a tubular member such as a nozzle, as long as it is capable of injecting the precursor gas. As shown in FIG. 2, partition walls are installed between the cylindrical portion and the portions 222a and 222c on both sides of the supply buffer 222 in the width direction W.

### (Third Injector)

As shown in FIG. 2, the substrate processing apparatus 10 according to the embodiments of the present disclosure further includes four counter nozzles 343d to 343g as a third injector configured to supply an assist gas. One or more of the four counter nozzles 343d to 343g may be installed at a position where an angle between the virtual plane A and a second virtual line L2 connecting the injection direction of each of the counter nozzles 343d to 343g and the center C1 of the wafer 200 is an obtuse angle in plane view.

The four counter nozzles 343d to 343g are accommodated inside the counter buffers 222d to 222g in a corresponding manner, respectively. The four counter buffers 222d to 222g are regions that are installed at the sidewall of the cylinder portion of the inner tube 12 and protrude outward from the sidewall, similar to the supply buffer 222. In this embodiment, the counter buffers 222d to 22g may be installed between the main exhaust slit 236 and the two sub-exhaust slits 238 in the circumferential direction of the cylinder portion or between the supply buffer 222 and the two sub-exhaust slits 238.

In the present disclosure, the counter nozzles 343d to 343g may not be provided. In addition, a temperature sensor may be disposed in the counter buffers 222d to 222g. Note that the third injector is not limited to a tubular member such as a nozzle, as long as it is capable of injecting the process gas.

### (Gas Supply System)

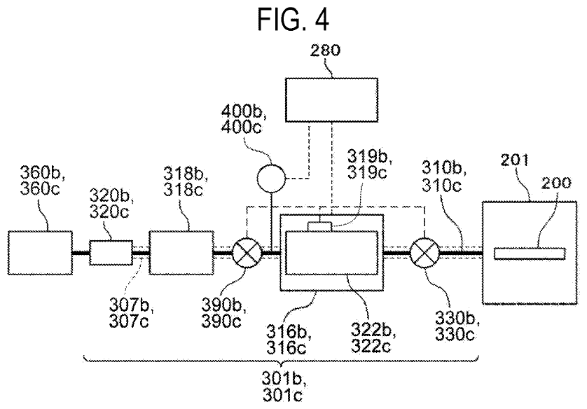

As shown in FIG. 4, the substrate processing apparatus 10 includes a first gas supply system 301b and a second gas supply system 301c. The first gas supply system 301b mainly includes the gas supply pipe 310b, the MFC 320b, the valve 390b, the tank 322b, and the valve 330b. The first gas supply system 301b supplies a gas accumulated in the tank 322b from the vaporizer 360b to the wafer 200 by the return nozzle 340. At least one selected from the group of the vaporizer 360b and the return nozzle 340 may be included in the first gas supply system 301b.

The second gas supply system 301c mainly includes the gas supply pipe 310c, the MFC 320c, the valve 390c, the tank 322c, and the valve 330c. The tank 322c of the second gas supply system 301c is the same in capacity as the tank 322b of the first gas supply system 301b. The tank 322c of the second gas supply system 301c accumulates the same type of gas as that accumulated in the tank 322b of the first gas supply system 301b. The second gas supply system 301c supplies the gas accumulated in the tank 322c from the vaporizer 360c to the wafer 200 by the return nozzle 341. At least one selected from the group of the vaporizer 360c and the return nozzle 340 may be included in the second gas supply system 301c.

### (Tank Heater and Thermocouple)

As shown in FIG. 4, at the tanks 322b and 322c, tank heaters 316b and 316c as temperature regulators (heaters) and thermocouples 319b and 319c as thermometers are installed. The tank heaters 316b and 316c are a pair of tank heaters of the present disclosure. The tank heaters 316b and 316c heat the tanks 322b and 322c to the same temperature, respectively.

The thermocouples 319b and 319c are connected to the control part 280. Based on the temperature information detected by the thermocouples 319b and 319c, power supplied to the tank heaters 316b and 316c from a power supply (not shown) is regulated. This controls the temperature of each of the tanks 322b and 322c to a desired temperature.

In the embodiment, the thermocouple 319b can measure both the temperature of the tank 322b and the internal temperature of the tank 322b. In addition, the thermocouple 319c can measure both the temperature of the tank 322c and the internal temperature of the tank 322c. Note that in the present disclosure, the thermometer may measure at least one selected from the group of the temperature of the tank and the internal temperature of the tank.

### (Pressure Sensor)

Pressure sensors 400b and 400c are installed on the upstream sides of the tanks 322b and 322c in a corresponding manner, respectively. The pressure sensors 400b and 400c are a pair of pressure gauges of the present disclosure configured to measure the internal pressure of each of the tanks 322b and 322c in which a gas is being accumulated.

### (Pipe Heater)

Pipe heaters 307b and 307c are arranged in the gas supply pipe 310b between an outlet of the MFCs 320b and 320c and the process chamber 201, respectively. The entire gas supply pipe 310b is heated by the pipe heaters 307b and 307c.

### (Preheater)

Preheaters 318b and 318c are arranged between the MFCs 320b and 320c and the valves 390b and 390c, respectively. The preheaters 318b and 318c include a plurality of heated baffles therein. This causes a large pressure loss for fluids with a high flow velocity. Therefore, at an initial stage of gas filling, internal pressures of pipes on secondary sides of the MFCs 320b and 320c can be kept high, and as a result, gas aggregation and multimerization due to temperature drop can be prevented.

Note that in the present disclosure, a flow path capable of increasing a pressure, such as an elbow or a divergent duct, may be installed, without being limited to a baffle. The divergent duct may be disposed immediately after the downstream side of the MFCs 320b and 320c. The divergent duct can increase the diameter of the pipe and raises the pressure, and then gradually reduce the diameter while heating the gas. In the divergent duct, the gas can be expanded isothermally.

### (Control Part)

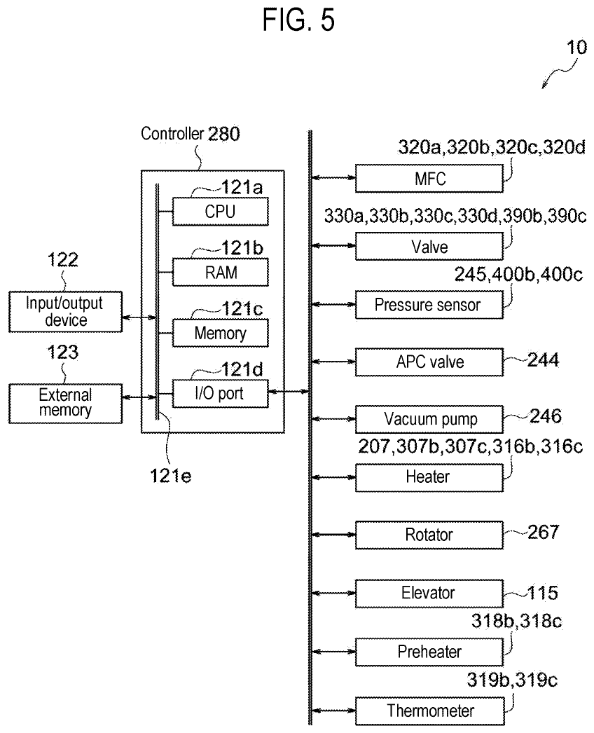

Next, the control part 280 will be described with reference to FIG. 5. FIG. 5 is a block diagram illustrating the substrate processing apparatus 10, and the control part 280 (i.e., a controller) of the substrate processing apparatus 10 is constituted as a computer. This computer includes a central processing unit (CPU) 121a, a random access memory (RAM) 121b, a memory 121c, and an I/O port 121d.

The RAM 121b, the memory 121c, and the I/O port 121d are configured to be capable of exchanging data with the CPU 121a via an internal bus 121e. An input/output device 122 configured as, for example, a touch panel is connected to the control part 280.

The memory 121c is constituted by, for example, a flash memory, a hard disk drive (HDD), etc. A control program that controls operations of the substrate processing apparatus, a process recipe in which procedures and conditions of substrate processing, which will be described later, are written, etc. are readably stored in the memory 121c.

The process recipe functions as a program that is combined to be capable of causing the control part 280 to execute each sequence in a substrate processing process, which will be described later, to obtain an expected result. Hereinafter, the process recipe and the control program may be generally and simply referred to as a “program.”

When the term “program” is used in the present disclosure, it may indicate a case of including the process recipe, a case of including the control program, or a case of including both the process recipe and the control program. The RAM 121b is constituted as a memory area (i.e., work area) in which programs, data, etc. read by the CPU 121a are temporarily stored. In addition, in the present disclosure, a computer-readable recording medium on which programs, data, etc. are recorded may be provided.

The I/O port 121d is connected to the above-described vaporizers 360a to 360d, MFCs 320a to 320d, preheaters 318b and 318c, valves 390a to 390d, valves 330a to 330d, pressure sensors 400b and 400c, pressure sensor 245, APC valve 244, vacuum pump 246, furnace heater 207, pipe heaters 307b and 307c, tank heaters 316b and 316c, temperature sensor, rotator 267, elevator 115, etc.

The CPU 121a is configured to read and execute the control program from the memory 121c and also to read the process recipe from the memory 121c in response to an input of an operation command from the input/output device 122. The CPU 121a is a processor of the present disclosure. The substrate processing apparatus has at least one processor.

The CPU 121a is configured to control the flow rate regulating operations of various gases by the MFCs 320a to 320d, the opening/closing operations of the valves 330a to 330d, and the opening/closing operations of the APC valve 244, according to the contents of the read process recipe. The CPU 121a is also configured to control the pressure regulating operation by the APC valve 244 based on the pressure sensor 245, the start and stop of the vacuum pump 246, and the temperature regulating operation of the furnace heater 207 based on the temperature sensor. The CPU 121a is further configured to control the rotation and rotation speed adjustment operation of the boat 217 by the rotator 267, the operation of raising or lowering operation of the boat 217 by the elevator 115, etc.

The control part 280 is not limited to being constituted as a dedicated computer, and may be constituted as a general-purpose computer. For example, the control part 280 of the embodiments of the present disclosure may be constituted by providing an external memory 123 storing the above-mentioned program, and installing the program in the general-purpose computer by using the external memory 123. Examples of the external memory may include a magnetic disk such as a hard disk, an optical disc such as a CD, a magneto-optical disc such as a MO, a semiconductor memory such as a USB memory, etc.

### <Method of Processing Substrate>

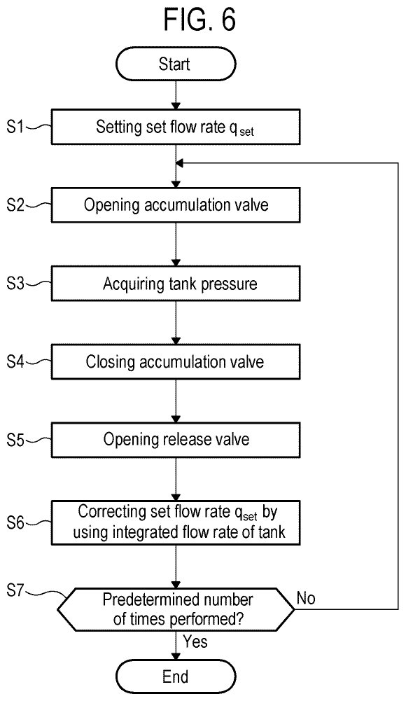

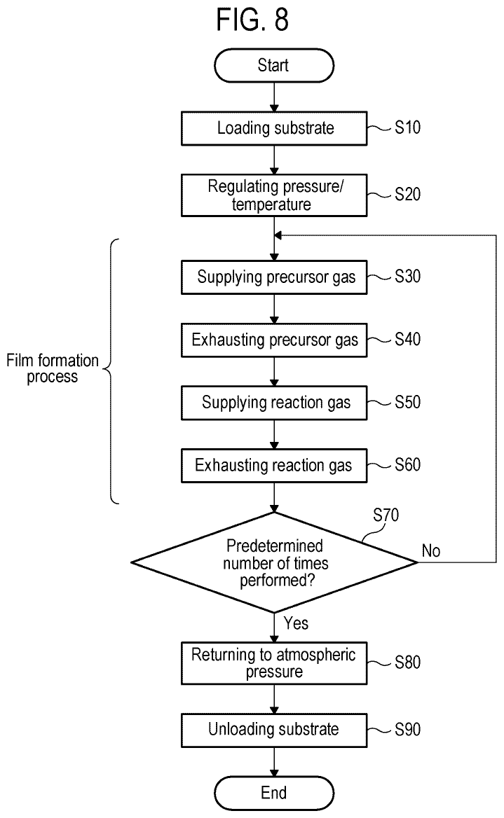

Next, a method of processing a substrate by using the substrate processing apparatus 10 according to the embodiments of the present disclosure will be described with reference to FIGS. 6 to 8. The method of processing the substrate according to the embodiments includes a set flow rate correction process illustrated in FIG. 6, which is performed before a film formation process, and the film formation process illustrated in FIG. 8. In addition, in the embodiments, a cycle process in which a film formation process is performed by alternately supplying a precursor gas and a reaction gas to the process chamber 201 will be described as an example of a process of manufacturing a semiconductor device.

### [Set Flow Rate Correction Process]

(Set Flow Rate qₛₑₜ Setting)

First, in the set flow rate correction process, as shown in step S1 in FIG. 6, an operator uses the control part 280 to evacuate the process chamber 201 and set preset set flow rates qₛₑₜ in the MFCs 320b and 320c, respectively.

Note that in the embodiments, a correction process to correct the set flow rate qₛₑₜ of the MFC 320b of the first gas supply system 301b will be described as an example, but in the present disclosure, the set flow rate qₛₑₜ of the MFC 320c of the second gas supply system 301c may be corrected. The correction process to correct the set flow rate qₛₑₜ of the MFC 320c of the second gas supply system 301c may be performed in the same manner as described below for the correction process of the MFC 320b, except that components constituting the first gas supply system 301b are replaced with components constituting the second gas supply system 301c.

### (Accumulation Valve Opening)

Next, as shown in step S2 in FIG. 6, the operator uses the control part 280 to open the valve 390b, which is an accumulation valve installed between the MFC 320b and the tank 322b in the first gas supply system 301b. By opening the valve 390b, a gas is accumulated in the tank 322b.

### (Tank Pressure Acquisition)

Next, as shown in step S3 in FIG. 6, the operator uses the control part 280 to acquire an internal pressure of the tank 322b during gas accumulation at a predetermined sample rate, thereby calculating a pressure gradient ΔPᵢ=Pᵢ−Pᵢ₋₁ per sample time. In this case, i is a natural number indicating the order in which the samples are acquired. In other words, the pressure gradient ΔPᵢ per sample time is a difference between the pressure Pᵢ acquired at the i-th sample time and the pressure Pᵢ₋₁ acquired at the (i−1)-th sample time immediately before the i-th sample time.

Then, a molar flow rate ΔQₘᵢ per sample time acquired at the i-th sample time can be calculated by using the pressure gradient ΔPᵢ and the following equation (1).

$$Δ {Q}_{mi} = \{ {V}_{T} / ( R \cdot T ) \} \cdot Δ {P}_{i} \qquad Equation ( 1 )$$

V_{T}: tank volume, R: gas constant, T: heating temperature of tank

In the present disclosure, the molar flow rate ΔQₘᵢ may be calculated according to the following equation (2).

$$Δ {Q}_{mi} = \{ ( {V}_{T} / R ) \cdot ( {P}_{i} - {P}_{i - 1} ) \} / ( {T}_{i + m} - {T}_{i + m - 1} ) \qquad Equation ( 2 )$$

Tᵢ: measured temperature of tank

A value after m samples corresponding to a difference in response time between the thermocouple and the pressure sensor is used as the measured temperature of the tank. Note that “m” used in Tᵢ₊ₘ and Tᵢ₊ₘ₋₁ in Equation (2) is a natural number.

### (Accumulation Valve Closing)

Next, as shown in step S4 in FIG. 6, the operator uses the control part 280 to accumulate the gas in the tank 322b for a time equal to a gas accumulation time T_{acm} set in the film formation process. After the gas is accumulated, the valve 390b is closed.

### (Release Valve Opening)

Next, as shown in step S5 in FIG. 6, the operator uses the control part 280 to evacuate the process furnace 202 and open the valve 330b, which is a release valve of the tank 322b, until the internal pressure of the tank 322b returns to a predetermined pre-accumulation pressure (e.g., about 100 kPa to about 1 kPa).

(Set Flow Rate qₛₑₜ Correction)

Next, as shown in step S6 in FIG. 6, the operator uses the control part 280 to calculate an integrated flow rate M1 according to the following equation (3).

$$M 1 = {\sum }_{0 < i \leq n} Δ {Q}_{mi} \qquad Equation ( 3 )$$

That is, the integrated flow rate M1 is a sum of the molar flow rates ΔQₘᵢ per sample time. The integrated flow rate M1 is calculated by integrating the pressure gradient measured multiple times during gas accumulation over the gas accumulation time. A ratio R1ⱼ=M_{std}/M1 between the calculated integrated flow rate M1 and a preset standard accumulation amount M_{std} is calculated.

Then, a corrected set flow rate can be obtained by multiplying a first correction coefficient α and a sum of the calculated ratios R1ⱼ by the set flow rate qₛₑₜ set in step S1, as shown in the following equation (4). N means that the processing of step S6 is performed N times.

$$( Set flow rate after correction ) = α \cdot ( {\prod }_{1 \leq j \leq N} R {1}_{j} ) \cdot {q}_{set} \qquad Equation ( 4 )$$

### (First Correction Coefficient)

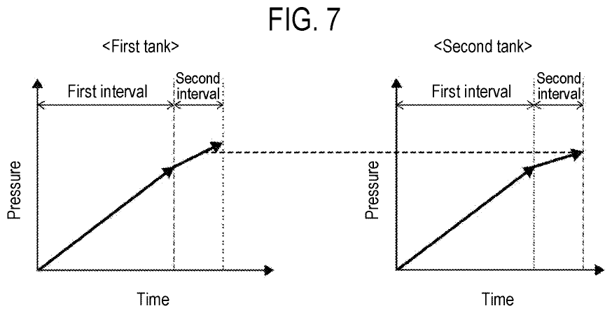

In the embodiments, as shown in FIG. 7, the gas accumulation time in the tanks 322b and 322c is divided into a first interval in which the MFCs 320b and 320c supply a gas at a set flow rate, and a second interval in which the MFCs 320b and 320c supply a gas at a flow rate less than the set flow rate. Then, the first correction coefficient α is set according to the following equation (5) during the accumulation of gas in the tank 322b or 322c.

$$( First correction coefficient α ) = ( length of the first interval + length of the second interval ) / length of the first interval \qquad Equation ( 5 )$$

That is, the first correction coefficient α in the embodiments is determined based on the ratio of the sum of the length of the first interval and the length of the second interval to the length of the first interval. Therefore, the first correction coefficient α in the embodiments is larger than 1, and as a result, the number of iterations of correction is reduced, that is, convergence of the set flow rate to an appropriate value can be accelerated. Note that in the embodiments of the present disclosure, the first correction coefficient can be set arbitrarily.

The corrected set flow rate {α·(Π_{1≤j≤N}Rⱼ)·qₛₑₜ} is set in the MFC 320b, such that the set flow rate of the MFC 320b is corrected to approach the standard accumulation amount M_{std}. In other words, the set flow rate of the MFC 320b is calibrated. Note that in the present disclosure, the integrated flow rate of the tank 322c of the second gas supply system 301c may be used as the standard accumulation amount M_{std} in the correction process of the first gas supply system 301b.

A mass flow rate measurer configured to measure a mass flow rate of gas may be installed between the tank and the MFC 320b or between the tank and the MFC 320c. For example, as the mass flow rate measurer, a mass flow meter may be installed on the downstream of the MFCs 320b and 320c. In the embodiments, the MFC 320b functions as the mass flow rate measurer. Then, the mass flow rate of gas measured by the mass flow rate measurer may be integrated to calculate the integrated flow rate.

In addition, in the present disclosure, a difference Dⱼ=M_{std}−M1 between the standard accumulation amount M_{std} and the integrated flow rate M1 may be calculated. Then, the set flow rate qₛₑₜ set in step S1 may be corrected by adding the product of the accumulation time T_{accm} of gas set in the film formation process, a second correction coefficient β, and the sum of the calculated differences Dⱼ to the set flow rate qₛₑₜ {(22.4/T_{accm})·β·(Σ1_{≤j≤N}Dⱼ)+qₛₑₜ}. In the present disclosure, at least one selected from the group of the ratio of the integrated flow rate to the standard accumulation amount and the difference between the integrated flow rate and the standard accumulation amount may be used for the correction.

### (Second Correction Coefficient)

In addition, in the embodiments of the present disclosure, the second correction coefficient β is set according to the above-described equation (5) during the accumulation of gas in the tank 322b or the tank 322c, similar to the first correction coefficient α. Therefore, similar to the first correction coefficient α, the second correction coefficient β in the embodiments is greater than 1, and therefore the convergence of the set flow rate to an appropriate value can be accelerated. Note that in the present disclosure, the second correction coefficient may be set arbitrarily, similar to the first correction coefficient.

For example, in the present disclosure, a pressure sensor configured to measure a pressure on a primary side of the flow rate limiter or a thermometer configured to measure a temperature on the primary side of the flow rate limiter may be installed. Then, at least one selected from the group of the first correction coefficient and the second correction coefficient may be changed by the control part 280 according to the pressure or temperature on the primary side of the flow rate limiter at a preset timing before the start of the second interval.

### (Performing Predetermined Number of Times)

Next, as shown in step S7 in FIG. 6, the operator performs the above-described steps S2 to S6 a predetermined number of times. In steps S2 to S6 at or after the second time (i.e., N≥2), the set flow rate corrected in the immediately preceding step S6 is used as the set flow rate to be corrected. That is, as the set flow rate to be corrected at or after the second time, a value of the set flow rate after the immediately preceding correction is treated as the “set flow rate qₛₑₜ” in steps S2 to S6. Therefore, an accuracy of the set flow rate is improved by repeating steps S2 to S6.

The above-described series of steps S1 to S7 constitute the correction process for set flow rate according to the embodiments. Then, after the set flow rate correction process is completed, a film formation process for the substrate is started by using the corrected set flow rate. In other words, the set flow rate correction process of the embodiments is a calibration process of the flow rate limiter or a second flow rate limiter that is performed before the film formation process.

### [Film Formation Process]

Next, in the cycle process as the film formation process, a Si precursor gas is used as an example of a source, and a N-containing gas is used as a reactant, such that a Si nitride film (Si₃N₄ film, hereinafter, also referred to as a SiN film) is formed on the wafer 200.

The SiN film is formed by performing a cycle a predetermined number of times (once or more times), the cycle including non-simultaneously performing a film formation step 1 in step S30, a film formation step 2 in step S40, a film formation step 3 in step S50, and a film formation step 4 in step S60 in FIG. 8.

The film formation step 1 is a step of supplying a precursor gas to the wafer 200 in the inner tube 12. The film formation step 2 is an exhaust step of removing the remaining precursor gas from the inner tube 12. The film formation step 3 is a step of supplying a reaction gas of a N-containing gas to the wafer 200 in the inner tube 12. The film formation step 4 is an exhaust step of removing the remaining reaction gas from the inner tube 12.

First, in step S10 in FIG. 8, the wafer 200 is charged into the boat 217. The boat 217 is loaded into the inner tube 12 to accommodate the substrate inside the cylindrical portion of the inner tube 12. Next, after the boat 217 is loaded into the inner tube 12, in step S20 in FIG. 8, the pressure and temperature in the inner tube 12 are regulated. Next, four steps of film formation steps 1 to 4 are executed sequentially. Each step will be described in detail below.

### (Film Formation Step 1)

In the film formation step 1, in step S30 in FIG. 8, the first injector is used to inject the precursor gas toward the wafer 200, while the main exhaust slit 236 and the two sub-exhaust slits 238 are used to exhaust the injected precursor gas to the outside of the cylindrical portion. Specifically, the flush supply is performed one or more times to instantly (i.e., in a relatively short time) release the precursor gas and a carrier gas from the gas nozzles 340a, 340b, 341a, and 341b.

As the precursor gas, for example, a Si- and halogen-containing gas may be used. As the Si- and halogen-containing gas, for example, inorganic chlorosilane-based gases such as a tetrachlorosilane (SiCl₄, abbreviation: STC) gas, a hexachlorodisilane (Si₂Cl₆, abbreviation: HCDS) gas, and an octachlorotrisilane (Si₃Cl₈, abbreviation: OCTS) gas may be used. One or more of these gases may be used as the Si- and halogen-containing gas.

The flush supply operation is performed intermittently, such that the precursor gas is adsorbed on the surface of the wafer 200. A film containing Si is formed on a base film of the wafer 200 by the adsorption.

In the flush supply, the accumulation of gas in the tank and the release of gas from the tank are performed substantially simultaneously.

In addition, in the flush supply, the accumulation of gas in the tank and the release of gas from the tank are repeated with a fixed time from the start of accumulation to the start of release.

### (Film Formation Step 2)

In the film formation step 2, in step S40 in FIG. 8, first, the supply of the precursor gas and the carrier gas is stopped. Next, by controlling an exhaust pump such as the vacuum pump 246, the APC valve 244, etc., the precursor gas is vacuum-exhausted so that the internal pressure of the reaction tube 203 reaches a predetermined pressure (i.e., degree of vacuum). By performing the vacuum-exhaust, the precursor gas remaining in the inner tube 12 is exhausted from the inner tube 12 to the outside. In the film formation step 2, in a case where an inert gas, for example, a N₂ gas, is supplied as a purge gas into the inner tube 12, the effect of exhausting the remaining precursor gas is further enhanced.

### (Film Formation Step 3)

In the film formation step 3, in step S50 in FIG. 8, the second injector is used to supply a reaction gas into the inner tube 12. The reaction gas may be, for example, a N-containing gas, a Si-free gas, an oxidizing gas, or a reducing gas such as hydrogen (H₂). In step S50, for example, a NH₃ gas is supplied as the reaction gas into the inner tube 12, while being exhausted from a plurality of exhaust slits. The supply of the N-containing gas causes a reaction between the Si-containing film on the base film of the wafer 200 and the N-containing gas. A SiN film is formed on the wafer 200 by the reaction. Alternatively, in a case where a mixture of O₂ gas and H₂ gas is used as the reaction gas, a SiO₂ film is formed.

### (Film Formation Step 4)

In the film formation step 4, in step S60 in FIG. 8, after forming the film, by controlling the exhaust pump such as the vacuum pump 246, the APC valve 244, etc., the reaction gas is vacuum-exhausted so that the internal pressure of the reaction tube 203 reaches a predetermined pressure (degree of vacuum). By the vacuum-exhaust, the N₂-containing gas remaining in the inner tube 12 after contributing to the film formation is exhausted from the inner tube 12 to the outside. In addition, in the film formation step 4, in a case where an inert gas, for example, a N₂ gas used as a carrier gas, is supplied as a purge gas into the inner tube 12, the effect of exhausting the remaining reaction gas of the N₂-containing gas from the inner tube 12 is further enhanced.

With the above-described film formation steps 1 to 4 as one cycle, in step S70 in FIG. 8, by performing the cycle of film formation steps 1 to 4 a predetermined number of times, a SiN film with a predetermined thickness can be formed on the wafer 200. In the embodiments, the film formation steps 1 to 4 are performed multiple times. In the present disclosure, the film formation steps 1 to 4 may be performed once at a time without being repeated.

After the above-described film formation process is completed, in step S80 in FIG. 8, the internal pressure of the inner tube 12 is returned to the normal pressure (i.e., the atmospheric pressure). Specifically, for example, an inert gas such as a N₂ gas is supplied into the inner tube 12 and is exhausted from the inner tube 12. As a result, the inner tube 12 is purged with the inert gas, and a gas remaining in the inner tube 12 is removed from the inner tube 12. Thereafter, an internal atmosphere of the inner tube 12 is replaced with the inert gas, and the internal pressure of the inner tube 12 is returned to the normal pressure.

Then, in step S90 in FIG. 8, the wafer 200 is unloaded from the inner tube 12, and the substrate processing according to the embodiments is completed. The above-described series of steps constitute the method of manufacturing the semiconductor device according to the embodiments.

### Operation and Effects

According to the embodiments of the present disclosure, one or more of the effects set forth below can be obtained.

The substrate processing apparatus 10 according to the embodiments includes the tank 322b, the return nozzle 340, and the first gas supply system 301b configured to supply the gas accumulated in the tank 322b to the wafer 200 via the return nozzle 340. Further, the substrate processing apparatus 10 includes the tank 322c with a capacity which is the same as that of the tank 322b, the return nozzle 341, and the second gas supply system 301c configured to supply the same type of gas accumulated in the tank 322c to the wafer 200.

To equalize amounts of the gases supplied to the wafer 200 from the first gas supply system 301b and the second gas supply system 301c respectively, amounts of gases accumulated in the tanks 322b and 322c respectively may be made equal to each other before supplying the gas to the wafer 200.

Herein, as a method of making the amounts of the gases stored in the tanks 322b and 322c respectively equal to each other, for example, a method is considered in which the internal pressure of each tank during gas supply is measured in real time, and the accumulation time of gas supplied to the tank is regulated by using a flow rate limiter based on the measured internal pressure.

In this regard, FIG. 7 shows an example of pressure fluctuation when the supply of the same type of gas to two tanks of the same capacity is started simultaneously at the same set flow rate by using a flow rate limiter connected to the upstream side of each tank. As shown in FIG. 7, the internal pressure of the tank fluctuates due to inflow of a gas whose temperature is changed to a low temperature by adiabatic expansion into the tank, pulsation of the flow rate limiter, etc. This causes a difference in the slope of the internal pressure rise of the two tanks (in other words, the pressure gradient).

In other words, it is difficult to stably and accurately measure the internal pressure of the tank during gas accumulation. This causes an error in the pressure measurement, and the error causes a difference between accumulation amounts of the gases inside the two tanks after the gas is accumulated in the tank.

In other words, when the flow rate limiter configured to limit the set flow rate of gas is used, it is difficult to equalize the accumulation amounts in the two tanks to the same standard accumulation amount in a case where measurement of the internal pressure of the tank alone is relied upon. This causes a difference in the amounts of the gases supplied to the substrate from the nozzles corresponding to the two tanks respectively, resulting in reduced uniformity of the film on the substrate and reduced S/C.

In the embodiments, the set flow rate of the MFC 320b is corrected based on the integrated flow rate to the tank 322b calculated by using the pressure gradient of the tank 322b during gas accumulation. Therefore, the accumulation amount of gas in the tank 322b and the accumulation amount of gas in the tank 322c are controlled to form the standard accumulation amount, such that the uniformity of the supply amount of the same type of gas supplied to the wafer 200 from each of the first gas supply system 301b and the second gas supply system 301c can be improved.

Note that in the embodiments, the case in which the number of gas supply systems is two is exemplified, but in the present disclosure, the number of gas supply systems is not limited to two and is any number of three or more. In other words, the uniformity of the supply amount of the same type of gas supplied to the wafer 200 can be improved by controlling the accumulation amount of gas in each tank of two or more arbitrary gas supply systems to form the standard accumulation amount.

In addition, in the embodiments, since the integrated flow rate of the tank is used in correcting the set flow rate, even in a case where pulsation of the flow rate limiter occurs, the pressure fluctuation is averaged by the integration. As a result, an influence of the pressure fluctuation on the pressure measurement can be suppressed, such that a measurement error can be reduced.

In addition, since the influence of the pressure fluctuation on the pressure measurement can be suppressed, the pressure during the accumulation of gas in the tanks 322b and 322c can be increased. As a result, it is possible to increase the supply flow rate and the supply pressure of the gas during the flush supply of the return nozzles 340 and 341, for example. Therefore, the S/C of the substrate can be further improved.

In addition, in the embodiments, since the integrated flow rate of the tank 322b is used in correcting the set flow rate, zero-point correction of the pressure sensor may not be performed.

In addition, in the embodiments, the control part 280 calculates the integrated flow rate by integrating the pressure gradient measured multiple times during gas accumulation over the gas accumulation time, and performs correction based on the ratio of the calculated integrated flow rate to the standard accumulation amount, or the difference between the calculated integrated flow rate and the standard accumulation amount. Therefore, the accuracy of the correction can be improved, and therefore, the uniformity of the supply amount of the same type of gas supplied to the wafer 200 from each of the first gas supply system 301b and the second gas supply system 301c can be further improved.

In addition, in the embodiments, the control part 280 calculates the integrated flow rate by integrating the mass flow rates of the gas measured by the MFCs 320b and 320c as mass flow rate measurers. Then, the control part 280 performs correction based on the ratio of the calculated integrated flow rate to the standard accumulation amount, or the difference between the calculated integrated flow rate and the standard accumulation amount. Therefore, the accuracy of the correction can be improved, and therefore, the uniformity of the supply amount of the same type of gas supplied to the wafer 200 from each of the first gas supply system 301b and the second gas supply system 301c can be further improved.

In addition, in the embodiments, the MFCs 320b and 320c are mass flow controllers. In addition, in a state in which the flow rate of the gas cannot be limited to the set flow rate, the control valves inside the MFCs 320b and 320c are fully open or fully closed. In other words, when the control valves are in a state between a fully-opened state and a fully-closed state, no operation to limit the flow rate of the gas occurs. Since no operation to limit the flow rate of the gas occurs, a life of the mass flow controller can be extended.

In addition, in the embodiments, the return nozzles 340 and 341 include four or more injection holes arranged in a plane parallel to the wafer 200. Therefore, the uniformity of the concentration distribution of the gas supplied toward the wafer 200 is improved, and therefore, it is easier to improve the uniformity of the film on the wafer 200 and the S/C.

In addition, in the embodiments, in the flush supply, the accumulation of gas in the tank 322b and the release of gas from the tank 322b are repeated with a fixed time from the start of accumulation to the start of release. Similarly, in the flush supply, the accumulation of gas in the tank 322c and the release of gas from the tank 322c are repeated with a fixed time from the start of accumulation to the start of release.

In other words, it is difficult to regulate the accumulation time of gas in the tank when relying on measurement of the internal pressure of the tank alone. For this reason, by correcting the set flow rate, effectiveness of the embodiments is particularly high in that the accumulation amount of gas in the tank 322b is controlled to form the standard accumulation amount.

In addition, in the embodiments, the accumulation of gas in the tank 322b and the release of gas from the tank 322b are performed substantially simultaneously, and the accumulation of gas in the tank 322c and the release of gas from the tank 322c are performed substantially simultaneously. Therefore, the number of times of supply of gas to the substrate can be increased as compared to when a gap is formed between the accumulation of gas and the release of gas.

In addition, in the embodiments, the control part 280 performs correction by multiplying the set flow rate by the ratio of the calculated integrated flow rate to the standard accumulation amount and the preset first correction coefficient α. Therefore, the accuracy of the correction can be further improved.

In addition, in the embodiments, the control part 280 can perform correction by adding a value, which is obtained by multiplying the difference between the calculated integrated flow rate and the standard accumulation amount with the preset second correction coefficient β, to the set flow rate. Therefore, the accuracy of the correction can be further improved.

In addition, in the embodiments, the first correction coefficient α and the second correction coefficient β are determined based on the ratio by using the length of the first main supply interval and the length of the first reduced supply interval. Therefore, the accuracy of the correction can be further improved.

In addition, in the embodiments, the first correction coefficient α and the second correction coefficient β can be changed according to the pressure or temperature of the primary side of the MFCs 320b and 320c at a preset timing before the start of the second interval. Therefore, the accuracy of the correction can be further improved.

In addition, in the embodiments, the vaporizers 360b and 360c vaporize a gas in a liquid state at a target temperature and provide the vaporized gas to the MFCs 320b and 320c, respectively, at a pressure determined according to the saturated vapor pressure at the target temperature. This makes it easier to improve the uniformity of the film on the wafer 200 and the S/C.

In addition, in the embodiments, the tank heaters 316b and 316c heat the tanks 322b and 322c, respectively, to the same temperature. This makes it easier to improve the uniformity of the film on the wafer 200 and the S/C.

In addition, in the embodiments, each of the MFCs 320b and 320c includes the orifice and the control valve configured to control the gas pressure on the primary side of the orifice, and controls the gas flow rate by using the choke flow of the orifice. This makes it easier to further improve the uniformity of the film on the wafer 200 and the S/C.

Similarly, in the method of processing the substrate by using the substrate processing apparatus 10 according to the embodiments, the accumulation amount of gas in the tank 322b and the accumulation amount of gas in the tank 322c are controlled to form the standard accumulation amount, such that the uniformity of the supply amount of the same type of gas supplied to the wafer 200 from each of the first gas supply system 301b and the second gas supply system 301c can be improved.

In addition, in the method of processing the substrate by using the substrate processing apparatus 10 according to the embodiments, the set flow rate is corrected before the film formation process on the substrate. Therefore, the uniformity of the film on the wafer 200 during film formation and the S/C can be improved.

In addition, in the method of manufacturing the semiconductor device by using the substrate processing apparatus 10 according to the embodiments, the uniformity of the supply amount of the same type of gas supplied to the wafer 200 from each of the first gas supply system 301b and the second gas supply system 301c can be improved. As a result, the uniformity of the film on the wafer 200 and the S/C can be improved.

In addition, in the gas supply system included in the substrate processing apparatus 10 according to the embodiments, the accumulation amount of gas in the tank 322b and the accumulation amount of gas in the tank 322c are controlled to form the standard accumulation amount, such that the uniformity of the supply amount of the same type of gas supplied to the wafer 200 from each of the first gas supply system 301b and the second gas supply system 301c can be improved.

In addition, in the gas supply program which uses the gas supply system according to the embodiments, the accumulation amount of gas in the tank 322b and the accumulation amount of gas in the tank 322c are controlled to form the standard accumulation amount, such that the uniformity of the supply amount of the same type of gas supplied to the wafer 200 from each of the first gas supply system 301b and the second gas supply system 301c can be improved.

### First Modification

The set flow rate correction process in the method of processing the substrate according to a first modification is mainly different from the set flow rate correction process according to the embodiments described with reference to FIG. 6 in that, instead of calculating the molar flow rate, an internal pressure Pe of the tank and an internal temperature Te of the tank are estimated at the timing of release of the gas from the tank.

In addition, the set flow rate correction process in the method of processing the substrate according to the first modification is mainly different from the set flow rate correction process according to the embodiments in that, instead of using the integrated flow rate, the accumulation amount of the tank is used to correct the set flow rate. Hereinafter, the set flow rate correction process of the method of processing the substrate according to the first modification will be mainly described with respect to the differences from the process in each step in FIG. 6, and description of the common process will not be duplicated as appropriate.

(Set Flow Rate qₛₑₜ Setting)

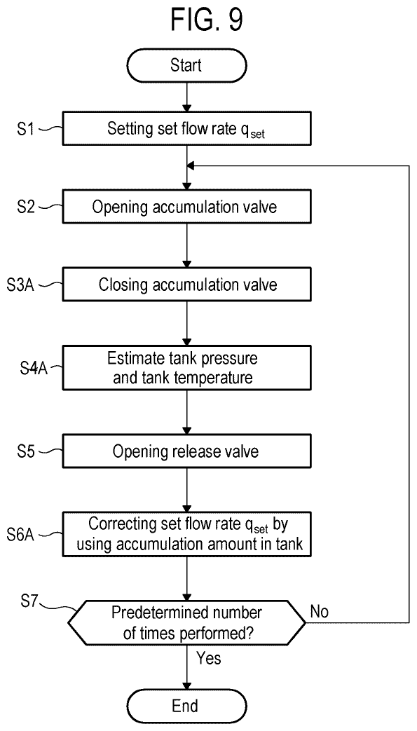

First, as shown in step S1 in FIG. 9, similar to step S1 in FIG. 6, the operator uses the control part 280 to evacuate the process chamber 201. In addition, the operator uses the control part 280 to set the preset set flow rates qₛₑₜ in the MFC 320b, which is a flow rate limiter, and the MFC 320c which is a second flow rate limiter, respectively.

### (Accumulation Valve Opening)

Next, as shown in step S2 in FIG. 9, similar to step S2 in FIG. 6, the operator uses the control part 280 to open the valve 390b, which is an accumulation valve installed between the MFC 320b and the tank 322b in the first gas supply system 301b. By opening the valve 390b, a gas is accumulated in the tank 322b.

### (Accumulation Valve Closing)

Next, as shown in step S3A in FIG. 9, the operator uses the control part 280 to accumulate the gas in the tank 322b for a time equal to the gas accumulation time T_{acm} set in the film formation process. After the gas is accumulated, the valve 390b is closed. That is, step S3A in FIG. 9 is the same as step S4 in FIG. 6.

### (Tank Pressure and Tank Temperature Estimation)

Next, as shown in step S4A in FIG. 9, the operator uses the control part 280 to set the estimated time from the closing of the valve 390b, which is the accumulation valve, to the opening of the valve 330b, which is the release valve, to be longer than the time during the film formation process. Then, the operator uses the control part 280 to acquire a plurality of values of the internal pressure and internal temperature of the tank during the set estimated time at a predetermined sample rate.

The measured pressure includes a pressure measured during the gas accumulation and a pressure measured after the gas accumulation is completed. Then, the operator uses the control part 280 to estimate the pressure Pe and temperature Te at the timing when the gas is released from the tank during the film formation process, from the plurality of acquired values by means of weighted average, linear approximation, or the like.

In a case where the pressure drops after accumulation, there is a possibility that the precursor of the gas may be aggregated in the tank. Herein, in a case where the precursor is aggregated in a cold spot of the pipe or tank, the aggregated precursor will not vaporize until the pressure drops. Therefore, it does not contribute to a peak flow rate in the flush supply from the return nozzles 340 and 341 to the wafer 200. Therefore, in the present disclosure, the aggregated precursor, such as re-liquefied precursor, is considered not to be accumulated in the tank.

### (Release Valve Opening)

Next, as shown in step S5 in FIG. 9, similar to step S5 in FIG. 6, the operator uses the control part 280 to evacuate the process furnace 202 and open the valve 330b, which is the release valve of the tank 322b, until the internal pressure of the tank 322b returns to a predetermined pre-accumulation pressure (e.g., about 100 kPa to about 1 kPa).

(Set Flow Rate qₛₑₜ Correction)

Next, as shown in step S6A in FIG. 9, the operator uses the control part 280 to calculate the tank accumulation amount M2 according to a gas state equation by using the following equation (6).

$$M 2 = ( Pe \cdot {V}_{T} ) / ( R \cdot Te ) \qquad Equation ( 6 )$$

Then, the ratio R2j=M_{std}/M2 between the calculated tank accumulation amount M2 and the preset standard accumulation amount M_{std} is calculated. Then, the set flow rate qₛₑₜ set in step S1 is corrected by multiplying the set flow rate qₛₑₜ by the first correction coefficient α and the sum of the calculated ratios R2ⱼ {α·(Π_{1≤j≤N}R2ⱼ)·qₛₑₜ}. The corrected set flow rate {α·(Π_{1≤j≤N}R2ⱼ)·qₛₑₜ} is set in the MFC 320b.

### (Performing Predetermined Number of Times)

Next, as shown in step S7 in FIG. 9, similar to step S7 in FIG. 6, the operator performs the above-described steps S2 to S6A a predetermined number of times. The above-described series of steps S1 to S7 constitute the set flow rate correction process according to the first modification. The other configurations of the set flow rate correction process according to the first modification are the same as those of the set flow rate correction process according to the embodiments.

### Operation and Effects of First Modification

In the first modification, the accumulation amount of gas in the tank 322b is estimated based on a plurality of pressures, including the pressures measured by the pressure sensors 400b and 400c during gas accumulation in the tank 322b and the pressures measured after the gas accumulation is completed, and the temperatures measured multiple times by the thermocouples 319b and 319c. In addition, the correction is performed based on the ratio of the estimated accumulation amount of gas to the standard accumulation amount, or the difference between the estimated accumulation amount of gas and the standard accumulation amount.

For this reason, as in the embodiments, the accumulation amount of gas in the tank 322b is controlled to form the standard accumulation amount, such that the uniformity of the supply amount of gas of the same type supplied to the wafer 200 from each of the first gas supply system 301b and the second gas supply system 301c can be improved. As a result, the uniformity of the film on the wafer 200 and the S/C can be improved. That is, the first modification also provides the same effects as the above-described embodiments.

Further, in the first modification, the integrated flow rate may not be used, and the set flow rate is corrected by using the accumulation amount in the tank, thereby making it possible to improve the uniformity of the film on the wafer 200 and the S/C. Other operations and effects of the first modification are the same as those of the embodiments, and therefore, description thereof will not be duplicated.

### Second Modification

In addition, as another method of correcting the set flow rate, for example, a correction value reflecting an error of control of the MFCs 320b and 320c and a correction value reflecting a mechanical difference in conductance when each of the control valves of the MFCs 320b and 320c is fully open can be used for correction.

Specifically, in the second modification, the control part 280 is used to set a first correction value based on the integrated flow rate calculated by the MFC 320b in, for example, the first interval of the tank 322b. In the present disclosure, the first correction value may be set based on the integrated flow rate calculated by the MFC 320c in the first interval of the tank 322c. The first correction value is a correction value reflecting the error of control of the MFCs 320b and 320c.

In addition, in the second modification, the control part 280 is used to set a second correction value based on the pressure gradient in the second interval of the tank 322b or the flow rate per unit time obtained by integrating the flow rate. In the present disclosure, the second correction value may be set based on the pressure gradient in the second interval of the tank 322c or the flow rate per unit time obtained by integrating the flow rate. The second correction value is a correction value reflecting the mechanical difference in conductance when the control valves of the MFCs 320b and 320c are fully open.

Then, for example, the set flow rate can be corrected by adding a combination of the first correction value and the second correction value, that is, a sum of the first correction value and the second correction value, to the set flow rate set in step S1 in FIG. 6.

### Operation and Effects of Second Modification

In the second modification, as in the embodiments, the accumulation amount of gas in the tank 322b is controlled to form the standard accumulation amount, such that the uniformity of the supply amount of the same type of gas supplied to the wafer 200 from each of the first gas supply system 301b and the second gas supply system 301c can be improved. As a result, the uniformity of the film on the wafer 200 and the S/C can be improved. That is, the second modification also provides the same effects as the above-described embodiments.

Further, in the second modification, the correction can be performed by using the correction value reflecting the error of control of the MFCs 320b and 320c and the correction value reflecting the mechanical difference in conductance when each of the control valves of the MFCs 320b and 320c is fully open. Other operations and effects of the second modification are the same as those of the embodiments, and therefore, description thereof will not be duplicated.

### Other Modifications

In addition, in the present disclosure, the timing at which the correction is reflected in the set flow rate is not limited to a case where it is reflected each time a correction value is obtained in one measurement. For example, correction values may be obtained in multiple measurements, and the obtained multiple correction values may be averaged and reflected in the set flow rate. This modification also provides the same effects as in the above-described embodiments. Further, in this modification, since the obtained multiple correction values are averaged and reflected in the set flow rate, the accuracy of the correction can be improved.

In addition, in the present disclosure, the object of correction may not be the set flow rate, but the temperature of the vaporizer. This modification also provides the same effects as the above-described embodiments. In addition, in this modification, the set flow rate may not be corrected, and the uniformity of the film on the wafer 200 and the S/C can be improved by correcting the temperature of the vaporizer.

### Other Aspects of the Present Disclosure

The present disclosure are described above according to aspects of the above-described embodiments, but the description and drawings forming a part of the present disclosure should not be understood as limiting the present disclosure. The present disclosure is not limited to the above-described embodiments, and various modifications can be made without departing from the gist of the disclosure.

For example, an example of forming the film by using a vertical batch-type substrate processing apparatus configured to process a plurality of substrates at a time are described in the above-described embodiments. However, the present disclosure is not limited to the above-described embodiments. The present disclosure can also be suitably applied to a case of forming a film by using, for example, a single-wafer type substrate processing apparatus configured to process one substrate at a time, or a multi-wafer type substrate processing apparatus configured to process a plurality of substrates at a time.

Further, an example of forming a film by using a substrate processing apparatus including a hot-wall type process furnace are described in the above-described embodiments. However, the present disclosure is not limited to the above-described embodiments, and can also be suitably applied to a case where a film is formed by using a substrate processing apparatus including a cold-wall-type process furnace.

Even when using these substrate processing apparatuses, each process can be performed by using the same processing procedures and process conditions as the above-described embodiments and modifications, and the same effects as in the above-described embodiments and modifications can be obtained.

Further, the present disclosure may be constituted by partially combining the configurations included in the above-disclosed embodiments, modifications, and aspects. In the present disclosure configured by the combination, the process procedures and process conditions to be executed can be constituted, for example, similarly to the processing procedures and process conditions described in the aspects related to the embodiments of the present disclosure.

The present disclosure includes various embodiments not described above, and the technical scope of the present disclosure is determined by the disclosure-specific matters of the claims that are reasonable from the above description.

According to the present disclosure, it is possible to improve uniformity of supply amounts of gases supplied to a substrate from two or more gas supply systems.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
(a) a pair of injectors each configured to supply a film formation gas toward a substrate;
(b) a pair of tanks connected to the pair of injectors respectively and configured to accumulate the gas;
(c) a pair of opening and closing valves configured to control fluid communication of the gas between the pair of injectors and the pair of tanks in a corresponding manner, respectively;
(d) a pair of pressure gauges configured to measure internal pressures of the pair of tanks, respectively, during the accumulation of the gas;
(e) a pair of flow rate limiters configured to supply the gas to the pair of tanks at a set flow rate set in advance to form a standard accumulation amount as a target amount of the gas, respectively; and
(f) a controller configured to be capable of performing:
accumulating the gas in one of the pair of tanks while controlling the fluid communication by a corresponding opening and closing valve of the pair of opening and closing valves;
measuring the internal pressure of the one of the pair of tanks by a corresponding pressure gauge of the pair of pressure gauges during the accumulation of the gas;
calculating an integrated flow rate of the gas to the one of the pair of tanks or an accumulation amount in the one of the pair of tanks; and
correcting the set flow rate so as to approach the standard accumulation amount based on the measured internal pressure and the calculated integrated flow rate or the calculated accumulation amount.

2. The substrate processing apparatus of claim 1, wherein the controller is further configured to be capable of performing:
calculating the integrated flow rate by integrating a pressure gradient measured multiple times during the accumulation of the gas over an accumulation time of the gas; and
performing the correction based on a ratio of the calculated integrated flow rate to the standard accumulation amount or a difference between the calculated integrated flow rate and the standard accumulation amount.

3. The substrate processing apparatus of claim 1, wherein a mass flow rate measurer configured to measure a mass flow rate of the gas is installed between the one of the pair of tanks and a corresponding flow rate limiter of the flow rate limiters, and
wherein the controller is further configured to be capable of performing:
calculating the integrated flow rate by integrating the mass flow rate of the gas measured by the mass flow rate measurer; and
performing the correction based on a ratio of the calculated integrated flow rate to the standard accumulation amount or a difference between the calculated integrated flow rate and the standard accumulation amount.

4. The substrate processing apparatus of claim 1, further comprising:
a thermometer configured to measure a temperature or an internal temperature of the one of the pair of tanks,
wherein the controller is further configured to be capable of performing:
estimating the accumulation amount of the gas inside the one of the pair of tanks based on a plurality of pressures including the internal pressure measured by the corresponding pressure gauge during the accumulation of the gas and the internal pressure measured after the accumulation of the gas is completed in the one of the pair of tanks, and based on the temperature measured multiple times by the thermometer; and
performing the correction based on a ratio of the estimated accumulation amount of the gas to the standard accumulation amount or a difference between the estimated accumulation amount of the gas and the standard accumulation amount.

5. The substrate processing apparatus of claim 1, wherein the pair of flow rate limiters are mass flow controllers, and
wherein in a state where a flow rate of the gas is not capable of being limited to the set flow rate, control valves inside the pair of flow rate limiters are fully open or fully closed.

6. The substrate processing apparatus of claim 1, wherein the pair of injectors are U-turn nozzles including four or more injection holes arranged in a plane parallel to the substrate, and
wherein the accumulation of the gas in the one of the pair of tanks and release of the gas from the one of the pair of tanks are repeated with a fixed time from start of the accumulation to start of the release.

7. The substrate processing apparatus of claim 6, wherein the accumulation of the gas in the one of the pair of tanks and the release of the gas from the one of the pair of tanks are performed substantially simultaneously.

8. The substrate processing apparatus of claim 2, wherein the controller is further configured to be capable of performing the correction by multiplying the set flow rate by a ratio of the integrated flow rate calculated in the one of the pair of tanks to the standard accumulation amount and a first correction coefficient set in advance.

9. The substrate processing apparatus of claim 2, wherein the controller is further configured to be capable of performing the correction by adding, to the set flow rate, a product of a difference between the calculated integrated flow rate in the one of the pair of tanks and the standard accumulation amount and a second correction coefficient set in advance.

10. The substrate processing apparatus of claim 8, wherein the accumulation time of the gas in the one of the pair of tanks is divided into a first interval in which a corresponding flow rate limiter of the pair of flow rate limiters supplies the gas at the set flow rate and a second interval in which the corresponding flow rate limiter supplies the gas at a flow rate less than the set flow rate, and
wherein the first correction coefficient is set based on a ratio of a sum of a length of the first interval and a length of the second interval to the length of the first interval.

11. The substrate processing apparatus of claim 2, wherein the controller is further configured to be capable of performing the correction before a film formation process on the substrate.

12. The substrate processing apparatus of claim 10, wherein the controller is further configured to be capable of changing the first correction coefficient according to a pressure or a temperature on a primary side of the corresponding flow rate limiter at a preset timing before start of the second interval.

13. The substrate processing apparatus of claim 2, further comprising:
a pair of vaporizers configured to vaporize the gas in a liquid state at a target temperature and provide the vaporized gas to the pair of flow rate limiters at a pressure determined according to a saturated vapor pressure at the target temperature, respectively.

14. The substrate processing apparatus of claim 13, further comprising:
a pair of tank heaters configured to heat the pair of tanks to the same temperature, respectively.

15. The substrate processing apparatus of claim 14, wherein each of the pair of flow rate limiters includes an orifice and a control valve configured to control a pressure of the gas on a primary side of the orifice, and controls a flow rate of the gas by using a choke flow of the orifice.

16. The substrate processing apparatus of claim 2, wherein the accumulation time of the gas in the one of the pair of tanks is divided into a first interval in which a corresponding flow rate limiter of the pair of flow rate limiters supplies the gas at the set flow rate and a second interval in which the corresponding flow rate limiter supplies the gas at a flow rate less than the set flow rate, and
wherein the controller is further configured to be capable of performing the correction by combining a first correction value set based on the integrated flow rate calculated by the corresponding flow rate limiter in the first interval and a second correction value set based on the pressure gradient in the second interval or a flow rate per unit time obtained by integrating the flow rate of the gas.

17. A gas supply system comprising:
(a) a pair of injectors each configured to supply a film formation gas toward a substrate;
(b) a pair of tanks connected to the pair of injectors respectively and configured to accumulate the gas;
(c) a pair of opening and closing valves configured to control fluid communication of the gas between the pair of injectors and the pair of tanks in a corresponding manner, respectively;
(d) a pair of pressure gauges configured to measure internal pressures of the pair of tanks, respectively, during the accumulation of the gas;
(e) a pair of flow rate limiters configured to supply the gas to the pair of tanks at a set flow rate set in advance to form a standard accumulation amount as a target amount of the gas, respectively; and
(f) a controller configured to be capable of performing:
accumulating the gas in one of the pair of tanks while controlling the fluid communication by a corresponding opening and closing valve of the pair of opening and closing valves;
measuring the internal pressure of the one of the pair of tanks by a corresponding pressure gauge of the pair of pressure gauges during the accumulation of the gas;
calculating an integrated flow rate of the gas to the one of the pair of tanks or an accumulation amount in the one of the pair of tanks; and
correcting the set flow rate so as to approach the standard accumulation amount based on the measured internal pressure and the calculated integrated flow rate or the calculated accumulation amount.

18. A method of processing a substrate in a substrate processing apparatus including a pair of tanks that are connected to a pair of injectors each configured to supply a film formation gas toward the substrate respectively, and configured to accumulate the gas, the method comprising:
accumulating the gas in one of the pair of tanks while controlling fluid communication;
measuring an internal pressure of the one of the pair of tanks during the accumulation of the gas;
calculating an integrated flow rate of the gas to the one of the pair of tanks or an accumulation amount in the one of pair of tanks; and
correcting a set flow rate of the gas supplied to each of the pair of tanks so as to approach a standard accumulation amount as a target amount of the gas based on the measured internal pressure and the calculated integrated flow rate or the calculated accumulation amount.

19. A method of manufacturing a semiconductor device, comprising the method of claim 18.

20. A non-transitory computer-readable recording medium storing a gas supply program that causes, by a computer, one or more processors to perform a process comprising the method of claim 18.
